(19) United States
(12) Patent Application Publication
(10) Pub. No.: US 2010/0003538 A1
(43) Pub. Date: Jan. 7, 2010

(54) Steel sheet provided with a corrosion protection system and method for coating steel sheet with such a corrosion protection system

(75) Inventors: Krasimir Nikolov, Dortmund (DE); Nicole Weiher, Bochum (DE); Bernd Schuhmacher, Dortmund (DE)

Correspondence Address: PROSKAUER ROSE LLP, ONE INTERNATIONAL PLACE, BOSTON, MA, 02110, US

(73) Assignee: ThyssenKrupp Steel AG

(21) Appl. No.: 12/299,710

(22) PCT Filed: May 18, 2007
(86) PCT No.: PCT/EP2007/054825

§ 371 Date: May 11, 2009

(30) Foreign Application Priority Data
May 18, 2006 (DE) 10 2006 023 230.5
Oct. 4, 2006 (DE) 10 2006 047 060.5

(51) Int. Cl. B32B 15/18; B32B 15/08; C23C 28/00; C23C 16/513

(52) U.S. Cl. 428/626; 427/569; 205/192

(57) ABSTRACT

A flat steel product provided with a coating system, which in the coated state possesses an optimized combination of corrosion resistance and welding capacity, includes a base layer formed from a steel and a corrosion protection system applied onto the base layer. The corrosion protection system comprises a metallic coating less than 3.5 μm thick, formed from a first metallic layer applied onto the base layer and a second metallic layer applied onto the first metallic layer, wherein the second metallic layer has formed a metallic alloy with the first metallic layer. The corrosion protection system also comprises a plasma polymer layer applied onto the metallic coating.

### CROSS-REFERENCE TO RELATED APPLICATIONS

This application is a National Phase Application of International Application No. PCT/EP2007/054825, filed on May 18, 2007, which claims the benefit of and priority to German patent application no. DE 10 2006 023 230.5, filed May 18, 2006, and German patent application no. DE 10 2006 047 060.5, filed Oct. 4, 2006. The disclosures of the above applications are incorporated herein by reference in their entirety.

### FIELD OF THE INVENTION

The invention relates to a flat steel product provided with a multi-layered corrosion protection system, such as sheet or strip, and a method for coating a flat steel product with a multi-layered protection system.

### BACKGROUND

In order to improve resistance against corrosion, metallic coatings are applied in particular on steel sheets, which in the majority of cases consist of zinc or zinc alloys. Such zinc or zinc alloy coatings, due to their barrier and cathodic protective effect, provide good protection against corrosion for the appropriately coated steel sheet when in practical application.

The thicker the coating, the greater the protective effect of the zinc coating becomes. High zinc coating thicknesses which guarantee a particularly good resistance to corrosion are offset, however, by the decreasing weldability with increasing coating thickness of the sheets to which the zinc coating has been applied. Accordingly, in practice, for example, problems then arise with processing if, by means of laser welding, through-welding of the parts to be connected to one another is to be produced at high welding speeds. Therefore, the requirements placed on the processing capacity of the sheets coated in the conventional manner with a zinc coating 5-15 μm thick, which today is used for example in the area of vehicle body construction or in the manufacture of domestic appliances, are frequently not fulfilled.

The corrosion resistance of zinc-coated sheets can indeed be further improved, with the thickness of the coating adjusted to average values of 7.5 μm, by the application of what is referred to as a “corrosion protection primer”. The application of such an additional coating, however, leads to a drastic reduction in the laser welding capacity. This possibility has therefore also not proved its worth for large-scale technical processing.

Against the background of problems with the weldability of conventional Zn-coated sheets, new highly corrosion-resistant Zn—Mg and Zn—Mg—Al coating systems have been developed, which with a perceptibly reduced coating thickness offer corrosion protection comparable to a conventional 7.5 μm thick zinc coating, but which lead to a significant improvement in suitability for laser welding.

One possibility of manufacturing hot-dip galvanized steel sheets of such a nature with increased corrosion resistance with simultaneously reduced coating weight is described in EP 0 038 904 B1. According to this prior art, by means of hot-dip coating a zinc coating containing 0.2% by weight Al and 0.5% by weight Mg is applied onto a steel substrate. The sheet coated in this manner has a better welding capacity with excellent resistance to rust formation.

Despite the reduction in the coating weight made possible by the method known, for example, from EP 0 038 904 B1, with simultaneous good corrosion resistance, the steel sheets coated in this manner still do not fulfil the requirements imposed for example in the area of motor vehicle body construction on the weldability of sheet metal parts, which in practical use are subjected to high loadings.

### SUMMARY OF THE INVENTION

In general, an aspect of the invention provides a flat steel product including a coating system which in the coated state has a combination of corrosion resistance and weldability optimized to such a degree that it is also capable of meeting the further increasing demands of processors of such sheets. In addition to this, a method for the manufacture of such sheets is to be described.

In an embodiment in accordance with the invention, a flat steel product has a base layer formed from a steel and a corrosion protection system applied onto the base layer. The corrosion protection system comprises a metallic coating less than 3.5 μm thick, formed from a first metallic layer applied onto the base layer and a second metallic layer applied onto the first metallic layer, wherein the second metallic layer has formed a metallic alloy with the first metallic layer, and comprises a plasma polymer layer applied onto the metallic coating.

In accordance with another embodiment, a method for the manufacture of a corrosion-resistant and readily weldable flat steel product, includes applying a first metallic layer onto a steel substrate forming the base layer of the flat steel product and applying a second metallic layer onto the first metallic layer, which, as a consequence of heat treatment, becomes an alloy with the first metallic layer, and wherein the total thickness of the metallic coating formed from the first and second metallic layers amounts to less than 3.5 μm, and a plasma polymer layer is applied onto the coating formed from the first and second metallic layers.

The thickness of the plasma polymer layer applied according to the invention onto the metallic coating is preferably restricted to a maximum of 2500 μm. It has surprisingly transpired that, in particular with lesser thicknesses of the plasma polymer layer, especially good properties of the steel sheet according to the invention can be guaranteed. As a result, the thickness of the plasma polymer layer is advantageously restricted to 100-1000 nm, in particular 200-500 nm.

With a steel strip or sheet according to the invention, having a multi-layer, thin corrosion protection system, an optimum combination of the advantages of the different corrosion protection properties of the different layers is achieved. Accordingly, a flat steel product according to the invention has a high resistance to corrosion both in the bare state and in combination with organic coatings. This high corrosion stability proves its worth in particular with regard to flanges and cavities. Tests on flange samples prepared in accordance with SEP 1160 and manufactured from steel sheets coated in accordance with the invention have shown that in the corrosion cyclic test in accordance with VDA test specification 621-415 a corrosion stability of more than 10 cycles without red rust is obtained.

A further surprising property possessed by a flat steel product according to the invention is demonstrated when such a sheet or strip is painted directly (without phosphating and passivation) by means of cathodic immersion painting. In a bend test carried out on the basis of DIN EN ISO 6860 for steel sheets or strips in accordance with the invention, an excellent paint adherence capacity resulted. No paint flaking and also no flaking of the coating from the base material was in evidence.

In addition to a high resistance to corrosion and an excellent paint adherence capacity, sheets according to the invention have good resistance to stone impact. Accordingly, in the stone impact tests carried out in accordance with DIN 55996-1B, it was proved that, with steel sheets according to the invention, no flaking of the coating from the base material is caused by stone impact.

In addition to a high resistance to corrosion, an excellent paint adherence capacity and good resistance to stone impact, sheets according to the invention have very good laser welding properties. This is demonstrated by the fact that hole-free laser seams could be achieved without or with only a very small proportion of pores and/or discharge craters, with a technical joint gap of 0 mm and welding speeds of up to 5 m/min. In addition to this, good spot welding could be demonstrated in the test carried out in accordance with ISO 14327.

The good corrosion resistance of the steel sheets or strips coated in accordance with the invention, in combination also with their inherently excellent paint adherence capacity, their good resistance to stone impact and their good spot-welding and laser-welding ability, make flat steel products according to the invention especially well-suited for use as materials for motor vehicle body construction or for the manufacture of domestic appliances.

With a metal sheet or strip coated in accordance with the invention, the thin, multi-layer corrosion protection system is formed from at least one layer, which guarantees electrochemical protection of the steel substrate forming the base layer, a layer lying on top of this which is capable of forming an alloy coating with the first layer and so leads to a perceptible improvement in the corrosion protection by means of additional electrochemical protection mechanisms of the metal sheet or strip, as well as from a further layer—the plasma polymer layer—which in its capacity as a barrier and/or passive layer leads to a further improvement in the corrosion protection.

With regard to the capacity for further processing, it is advantageous in this context if the total thickness of the metallic coating according to the invention is less than 3.5 μm and if also the thickness of the plasma polymer layer applied onto the metallic layer is restricted to less than 2500 nm. Surprisingly, it has been demonstrated that, despite the advantageously minimized thickness of the coating according to the invention, the corrosion resistance required by the users of sheets and strips obtained according to the invention is still provided.

The first metallic layer can be, for example, a pure zinc coating, which can be applied onto the steel substrate economically by conventional means by electrolytic galvanizing, hot-dip galvanizing, or vacuum depositing. As an alternative, the first metallic coating may also consist of Al, a Zn—Ni, a Zn—Fe, or a Zn—Al alloy.

Preferably, the second layer of the coating system according to the invention is a zinc alloy coating (Zn—Y). This zinc alloy coating is formed if a metal is applied onto the first layer which forms a Zn alloy with the first layer containing Zn. For this purpose, the metallic second layer becoming an alloy with the first layer can, for example, be deposited on the first layer by thermal evaporation, preferably carried out in a vacuum. This method is particularly well-suited if the second metallic layer is a fine-structured magnesium layer with a thickness of 100-2000 nm, preferably 100-1000 nm.

As well as Mg, other metals have proved to be suitable materials for the second metallic layer. Accordingly, for example by using Al, Ti, Cr, Mg, Ni, or their alloys, the demands placed on the second layer in each case can be fulfilled.

The plasma polymer layer applied according to the invention onto the metallic coating can, for example, be formed from organo-silane compounds, hydrocarbon compounds, organo-metallic compounds or their mixtures.

A particularly uniform formation of the plasma polymer layer applied according to the invention onto the metallic coating can be achieved by the plasma polymer layer being deposited by means of hollow cathode glow discharge. With hollow cathode glow discharge, high plasma densities and correspondingly high deposition rates can be achieved. Accordingly, this possibility for producing the plasma polymer layer is particularly well-suited for large-scale technical application in run-through techniques, and can be integrated into existing run-through coating systems, e.g. electrolytic galvanizing systems or hot-dip coating systems. In this situation, good processing results are achieved if the deposition rate of the hollow cathode glow discharge amounts to 10-1000 nm/s. The coating result can be improved further if the deposition rate of the hollow cathode glow discharge is set to 20-750 nm/s, wherein an optimum provision of the plasma polymer layer is achieved if the deposition rate of the hollow cathode glow discharge amounts to 50-500 nm/s, in particular 50-360 nm/s.

The heat treatment carried out according to the invention after the application of the metallic layers of the coating system is preferably carried out at temperatures below 500° C.

The heat treatment carried out to form alloying between the first and second metallic layers can be applied before or after the application of the plasma polymer layer. Regardless of when it is carried out, it provides good binding of the alloying layer and therefore inherently a good corrosion protection effect, with, at the same time, excellent laser welding capacity.

Surprisingly, it has been shown that in a carrying out a process in which, preferably, a subsequent heat treatment is not carried out until after the application of the metallic layers and of the plasma polymer layer, a positive effect on the alloying process between Zn and Mg is achieved. Accordingly, the method according to the invention differs from those methods from the prior art in which the metallic layer system is produced by means of deposition of a fine-structured magnesium layer, heat-evaporated in a vacuum, with a thickness of 100 . . . 2000 nm, in particular 100-1000 nm, on a zinc coating deposited by means of electrolytic galvanizing or hot-dip galvanizing or vacuum deposition and subsequent heat treatment, in that the alloying process is carried out before or only after the deposition of the plasma polymer layer by subsequent heat treatment.

An advantage of this procedure lies in the fact that the strip can be coated in series in a vacuum without coming into contact with the atmosphere in the course of carrying out the process.

### BRIEF DESCRIPTION OF THE DRAWINGS

FIG. 1 is a micrograph showing a cross-sectional view of a multi-layer corrosion protection system according to an embodiment of the invention.

FIG. 2 is a micrograph showing a cross-sectional view of a multi-layer corrosion protection system according to an embodiment of the invention.

### DESCRIPTION

The invention is described in greater detail hereinafter on the basis of embodiments.

### Example 1

A steel strip for deep-drawing purposes comprises a base layer, manufactured, for example, from a low-alloyed steel, onto which a thin, multi-layered corrosion protection system is applied.

The corrosion protection system in this situation is formed by a zinc coating, applied as a first metallic layer onto the base layer, the thickness of which amounts to approx. 3.4 μm, a second metallic layer applied onto the first metallic layer in the form of a Zn—Mg alloying coating, the thickness of which amounts to less than 1 μm, so that the metallic layers together are less than 3.5 μm thick, and a 340 nm thick plasma polymer layer. The thickness of the plasma polymer layer was varied. Thus, for example, plasma polymer layers with a thickness of 340 nm and 520 nm were deposited.

The corrosion protection layer, such as the layers described above with a plasma polymer layer of at least 340 nm thick, provides a corrosion stability in flange samples manufactured from the steel strip in accordance with SEP 1160 of at least 10 cycles in the corrosion cycle test in accordance with VDA Test Specification 621-415 without red rust. With steel sheets conventionally coated with a Zn—ZnMg coating system without a plasma polymer layer, examined as a reference, at this point in time more than >80-100% red rust was present.

With a corrosion protection system built up in an analogous manner and with a plasma polymer layer 520 nm thick, an even higher corrosion resistance could be demonstrated.

### Example 2

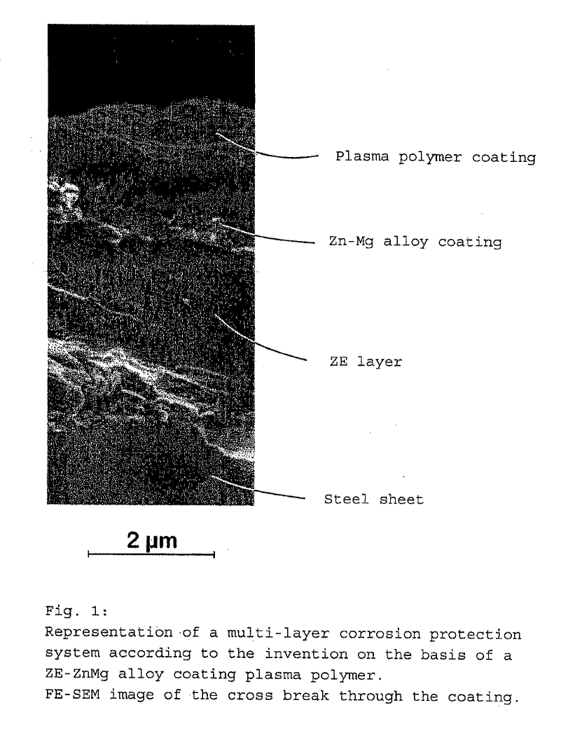

The manufacture of the thin, multi-layered corrosion protection system represented in FIG. 1 on an IF steel sheet has firstly had a zinc layer deposited on the IF steel substrate forming the base layer by means of electrolytic galvanizing. Next, a fine-structured magnesium coating was applied onto the zinc layer by thermal evaporation in a vacuum. With subsequent heat treatment at 310° C. a Zn—Mg alloying coating was obtained and finally a plasma polymer layer was deposited by means of hollow cathode glow discharge using tetramethyl silane with a deposition rate of 34 nm/s.

The steel sheet obtained in this way had excellent corrosion protection with simultaneously very good laser welding capability.

### Example 3

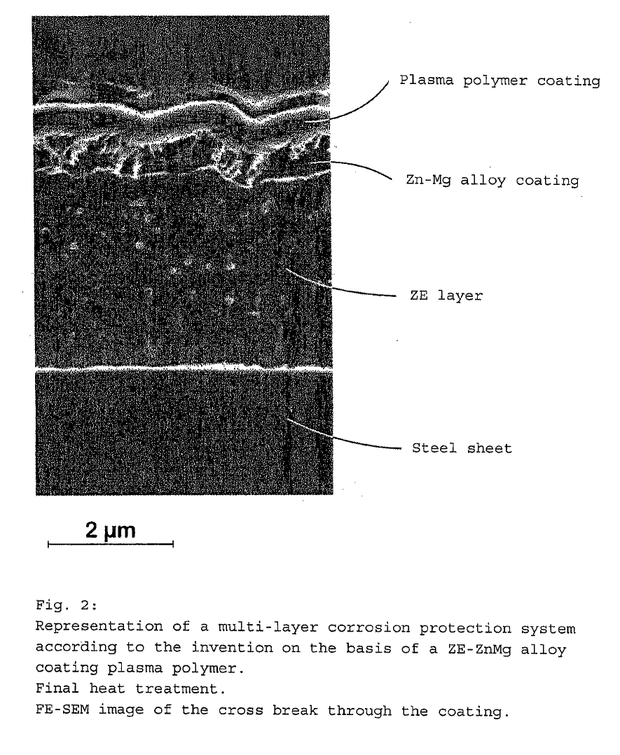

In order to produce the thin, multi-layer corrosion protection system represented in transverse section in FIG. 2 on a fine steel sheet forming the base layer, as a first step a Zn coating was deposited on the base layer as a first metallic layer by means of electrolytic galvanizing. Next, a fine-structured magnesium layer was deposited by thermal evaporation in a vacuum as a second metallic layer on the first metallic layer and a plasma polymer layer was deposited on the second metallic layer by means of hollow cathode glow discharge using tetramethyl silane, with a deposit rate of 34 nm/s. Only after the application of the plasma polymer layer on the second metallic layer was a heat treatment of 10 s at 335° C. carried out to form the Zn—Mg alloying coating.

The steel sheet obtained in this manner also had excellent corrosion protection with simultaneously very good laser welding capability.

With the procedure according to the invention, the corrosion coating can be produced free of interruption in an “in-line process sequence” in a vacuum, so that manufacturing costs are reduced and processing is simplified as a whole.

1. Flat steel product with a base layer formed from a steel and a corrosion protection system applied onto the base layer, the corrosion protection system comprising a metallic coating less than 3.5 μm thick, formed from a first metallic layer applied onto the base layer and a second metallic layer applied onto the first metallic layer, wherein the second metallic layer has formed a metallic alloy with the first metallic layer, and comprises a plasma polymer layer applied onto the metallic coating.

2. Flat steel product according to claim 1, wherein the plasma polymer layer is a maximum of 2500 μm thick.

3. Flat steel product according to claim 2, wherein the plasma polymer layer is 100-1000 nm thick.

4. Flat steel product according to claim 3, wherein the plasma polymer layer is 200-500 nm thick.

5. Flat steel product according to claim 1, wherein the first metallic layer is a Zn, an Al, a Zn—Ni, a Zn—Fe, or a Zn—Al coating.

6. Flat steel product according to claim 1, wherein the second metallic layer is a zinc alloy coating.

7. Flat steel product according to claim 1, wherein the second metallic layer is formed from at least one of the elements from the group Mg, Al, Ti, Cr, Mn, Ni or their alloys.

8. Flat steel product according to claim 1, wherein the thickness of the second layer amounts to 100-2000 nm.

9. Flat steel product according to claim 8, wherein the thickness of the second layer amounts to 200-1000 nm.

10. Flat steel product according to claim 1, wherein the plasma polymer layer is formed from organo-silane compounds, hydrocarbon compounds, organo-metallic compounds or their mixtures.

11. Method for the manufacture of a flat steel product coated with a corrosion protection system, in which a first metallic layer is applied onto a steel substrate forming the base layer of the flat steel product and a second metallic layer is applied onto the first metallic layer, which, as a consequence of heat treatment, becomes an alloy with the first metallic layer, wherein the total thickness of a metallic coating formed from the first and second metallic layers amounts to less than 3.5 μm, in which a plasma polymer layer is applied onto the metallic coating formed from the first and second metallic layers.

12. Method according to claim 11, wherein the plasma polymer layer is a maximum of 2500 μm thick.

13. Method according to claim 12, wherein the plasma polymer layer is 100-1000 nm thick.

14. Method according to claim 13, wherein the plasma polymer layer is 200-500 nm thick.

15. Method according to claim 11, wherein the first metallic layer is a zinc layer, which is applied by electrolytic galvanizing, hot-dip galvanizing, or vacuum evaporation onto the base layer.

16. Method according to claim 11, wherein the first metallic layer is formed from an Al, a Zn—Ni, a Zn—Fe or a Zn—Al compound.

17. Method according to claim 11, wherein the second metallic layer is a layer containing magnesium.

18. Method according to claim 11, wherein the second metallic layer is formed from Al, Ti, Cr, Mn, Ni or their alloys.

19. Method according to claim 11, wherein the second metallic layer is deposited on the first layer by thermal evaporation.

20. Method according to claim 11, wherein the plasma polymer layer is deposited by means of hollow cathode glow discharge.

21. Method according to claim 20, wherein a deposition rate of the hollow cathode glow discharge is 10-1000 nm/s.

22. Method according to claim 21, wherein the deposition rate of the hollow cathode glow discharge is 20-750 nm/s.

23. Method according to claim 22, wherein the deposition rate of the hollow cathode glow discharge is 50-500 nm/s.

24. Method according to claim 23, wherein the deposition rate of the hollow cathode glow discharge is 50-360 nm/s.

25. Method according to claim 11, wherein a temperature of the heat treatment is less than 500° C.

26. Method according to claim 11, wherein the heat treatment is carried out before application of the plasma polymer layer.

27. Method according to claim 11, wherein the heat treatment is carried out after application of the plasma polymer layer.
